(19) United States
(12) Patent Application Publication
(10) Pub. No.: US 2010/0243044 A1
(43) Pub. Date: Sep. 30, 2010

(54) PHOTOVOLTAIC CELL STRUCTURE

(75) Inventors: FENG FAN CHANG, KAOHSIUNG CITY (TW); HSIN HUNG LIN, YILAN COUNTY (TW); HSIN CHIH LIN, TAICHUNG CITY (TW); CHI HAU HSIEH, KAOHSIUNG CITY (TW); TZUNG ZONE LI, YUNLIN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: RITDISPLAY CORPORATION

(21) Appl. No.: 12/507,930

(22) Filed: Jul. 23, 2009

(30) Foreign Application Priority Data
Mar. 26, 2009 (TW) 098109842

(51) Int. Cl. H01L 31/02; H01L 31/0328; H01L 31/0272

(52) U.S. Cl. 136/256; 136/262; 136/264; 136/265

(57) ABSTRACT

A photovoltaic cell structure includes a substrate, a metal layer, a p-type semiconductor layer, an n-type semiconductor layer, a transparent conductive layer and a high resistivity layer. The metal layer is formed on the substrate. The p-type semiconductor layer is formed on the metal layer and may include a compound of copper indium gallium selenium sulfur (CIGSS), copper indium gallium selenium (CIGS), copper indium sulfur (CIS), copper indium selenium (CIS) or a compound of at least two of copper, selenium or sulfur. The n-type semiconductor layer exhibits photo catalyst behavior that can increase carrier mobility by receiving light, and is formed on the p-type semiconductor layer, thereby forming a p-n junction. The transparent conductive layer is formed on the n-type semiconductor layer. The high resistivity layer is formed between the metal layer and the transparent conductive layer.

### BACKGROUND OF THE INVENTION

(A) Field of the Invention

The present invention relates to a photovoltaic cell structure, and more specifically, to a thin-film photovoltaic cell structure including Copper Indium Gallium Selenium (CIGS) or Copper Indium Selenium (CIS).

(B) Description of the Related Art

Normally, Copper Indium Gallium Diselenide thin-film solar cells are one of two types; one is comprised of copper, indium and selenium, and another is comprised of copper, indium, gallium and selenium. Because of the high photoelectrical efficiency and low material cost, solar cell development is expected to continue at a rapid pace. The photoelectrical efficiency of CIGS solar cells in the laboratory can reach around 19%, and 13% for related solar cell modules.

FIG. 1 shows a traditional CIGS photovoltaic cell structure 10, which is a laminate structure. The photovoltaic cell structure 10 includes a substrate 11, a metal layer 12, a CIGS layer 13, a buffer layer 14 and a transparent conductive layer (TCO) 15. The substrate 11 may be a glass substrate, and the metal layer 12 may be a molybdenum metal layer to comply with the chemical characteristics of CIGS and withstand high temperature while the CIGS layer 13 is deposited. The CIGS layer 13 is a p-type semiconductor layer. The buffer layer 14, which is an n-type semiconductor layer that may be made of cadmium sulfate (CdS), and the CIGS layer 13 form a p-n junction therebetween. The transparent conductive layer 15 may be zinc oxide (ZnO) with doped aluminum (AZO) or the like. The transparent conductive layer 15 is also called a window layer, and allows light to pass through and reach the CIGS layer 13 beneath it.

Cadmium is toxic and is severely harmful to human beings if eaten. If photovoltaic cells include cadmium, e.g., the buffer layers include CdS, and used photovoltaic cells are not properly disposed, the environment will be contaminated and human health will be impacted.

Moreover, CdS is usually made by chemical bath deposition (CBD), and as a result a large amount of waste liquid is generated during manufacturing, resulting in contamination to environment.

Therefore, recent research has focused on finding an alternative for CdS so as to resolve the problems caused by its use.

### SUMMARY OF THE INVENTION

The present invention provides a photovoltaic cell structure, in which an n-type semiconductor layer having photo catalyst characteristic in place of the use of cadmium is formed in the cell structure, thereby eliminating much of the waste liquid and related cadmium contamination created by the manufacturing process.

According to an embodiment of the present invention, a photovoltaic cell structure includes a substrate, a metal layer, a p-type semiconductor layer, an n-type semiconductor layer, a transparent conductive layer and a high resistivity layer. The metal layer is formed on the surface of the substrate. The p-type semiconductor layer is formed on the metal layer and includes copper indium gallium selenium sulfur (CIGSS), copper indium gallium selenium (CIGS), copper indium sulfur (CIS), copper indium selenium (CIS) or includes a compound of at least two of copper, selenium or sulfur. The n-type semiconductor layer is formed on the p-type semiconductor layer so as to form a p-n junction therebetween. The n-type semiconductor layer exhibits photo catalyst behavior, i.e., the carrier mobility is increased by illumination. The transparent conductive layer is formed on the n-type semiconductor layer. The high resistivity layer is formed between the metal layer and the transparent conductive layer. For example, the high resistivity layer is stacked between and is in contact with the metal layer and the p-type semiconductor layer, or the n-type semiconductor layer and the transparent conductive layer.

In an embodiment, the n-type semiconductor layer may include titanium oxide (TiO₂) or tungsten oxide (WO₃) and have a thickness between 1 and 1000 nm. For example, titanium oxide becomes active when illuminated and thus exhibits photo catalyst behavior. Therefore, titanium oxide can be substituted for CdS as the material of n-type semiconductor layer and is less harmful to the environment.

### BRIEF DESCRIPTION OF THE DRAWINGS

FIG. 1 shows a known photovoltaic cell structure;

FIG. 2 shows a photovoltaic cell structure in accordance with a first embodiment of the present invention; and

FIG. 3 shows a photovoltaic cell structure in accordance with a second embodiment of the present invention.

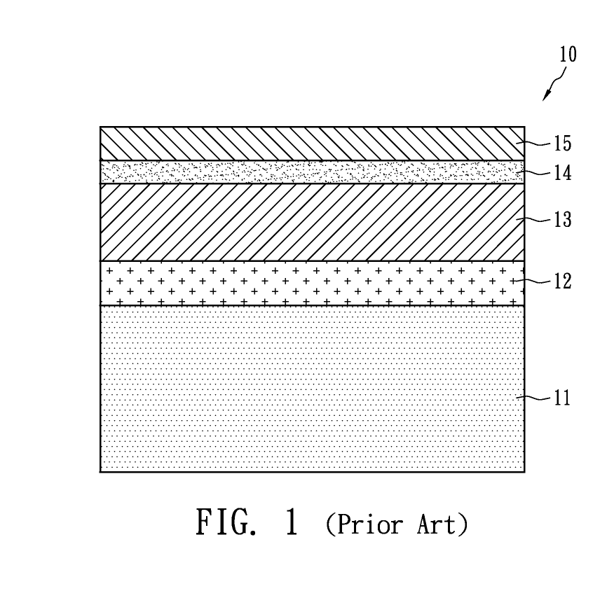

### DETAILED DESCRIPTION OF THE INVENTION

The making and use of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

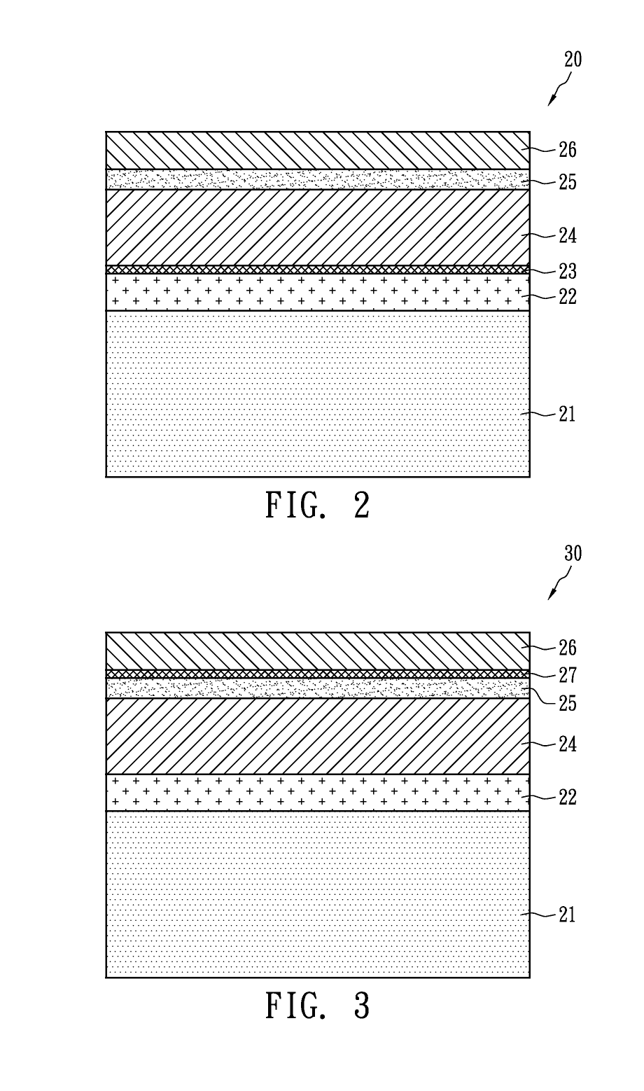

FIG. 2 shows a photovoltaic cell structure in accordance with a first embodiment of the present invention. A photovoltaic cell structure 20 is a laminated structure and includes a substrate 21, a metal layer 22, a high resistivity layer 23, a p-type semiconductor layer 24, an n-type semiconductor layer 25 and a transparent conductive layer 26. In addition to a glass substrate, the substrate 21 may be a polyimide flexible substrate, or a metal plate or a metal foil of stainless steel, molybdenum, copper, titanium or aluminum. The substrate 21 is used for film formation and the shape thereof is not restricted to a plate; others such as a ball or specific or arbitrary shapes can also be used. The metal layer 22 may be a molybdenum, chromium, vanadium or tungsten layer of a thickness between 0.5 and 1 μm formed on the surface of the substrate 21 to create a back contact metal layer of the cell. The high resistivity layer 23 is formed on the metal layer 22 and has a thickness preferably between 25 and 2000 angstroms. The p-type semiconductor layer 24 is formed on the surface of the high resistivity layer 23 and may include a compound of copper indium gallium selenium sulfur (CIGSS), copper indium gallium selenium (CIGS), copper indium sulfur (CIS), copper indium selenium (CIS) or a compound of at least two of copper, selenium or sulfur. The thickness of the p-type semiconductor layer 24 may be between 2 and 3 micrometers. The n-type semiconductor layer 25 is formed on the p-type semiconductor layer 24, thereby forming a p-n junction therebetween. The transparent conductive layer 26 is formed on the surface of the n-type semiconductor layer 25 and may be indium tin oxide (ITO), indium zinc oxide (IZO), aluminum zinc oxide (AZO), gallium zinc oxide (GZO), aluminum gallium zinc oxide (GAZO), cadmium tin oxide (CTO), zinc oxide (ZnO), zirconium dioxide (ZrO₂) or other transparent conductive materials.

In an embodiment, the n-type semiconductor layer 25 may be metal oxide such as titanium oxide (TiO₂), tungsten oxide (WO₃) or a semiconductor has the photo catalyst characteristic. They become active (exhibiting high carrier mobility rate) when illuminated, and therefore have photo catalyst characteristics. Such metal oxides can be substituted for CdS as material of the n-type semiconductor layer 25. In an embodiment, the thickness of the n-type semiconductor layer 25 is between 1 and 1000 nm.

The high resistivity layer 23 may be metal oxide or metal nitride. The metal oxide includes vanadium oxide, tungsten oxide, molybdenum oxide, copper oxide, iron oxide, tin oxide, titanium oxide, zinc oxide, zirconium oxide, lanthanum oxide, niobium oxide, indium tin oxide, strontium oxide, cadmium oxide, indium oxide, or the mixture or alloys thereof. Moreover, insulation materials including silicon, aluminum oxide or the like that can induce capacitive effect also can be the material of the high resistivity layer 23.

FIG. 3 shows a photovoltaic cell structure in accordance with a second embodiment of the present invention. A photovoltaic cell structure 30 is a laminated structure and includes a substrate 21, a metal layer 22, a p-type semiconductor layer 24, an n-type semiconductor layer 25, a high resistivity layer 27 and a transparent conductive layer 26. In comparison with the photovoltaic cell structure 20 shown in FIG. 2, the position of the high resistivity layer 27 is changed. The high resistivity layer 23 is initially placed between the metal layer 22 and the p-type semiconductor layer 24. Instead, the high resistivity layer 27 is placed between the n-type semiconductor layer 25 and the transparent conductive layer 26. In an embodiment, the high resistivity layer 27 comprises zinc oxide, which is also insulative for prevention of electrical shorts of devices. Likewise, the n-type semiconductor layer 25 can be made of photo catalyst material such as titanium oxide or tungsten oxide.

In an embodiment, the electrical experiment results of the photovoltaic cell with an n-type semiconductor layer exhibiting photo catalyst behavior is shown in the following table

| Jsc | Voc | Jmax | Vmax | Fill Factor | Efficiency |
|---|---|---|---|---|---|
| (mA/cm²) | (V) | (mA/cm²) | (V) | (a.u.) | (%) |
| 37.8 | 0.41 | 17.40 | 0.32 | 0.68 | 10.53 |

Jsc is short current density, Voc is an open voltage, Jmax is current density of maximum power, Vmax is a voltage of maximum power.

Because carrier mobility of a photo catalyst can be increased by illumination, Jsc and efficiency of a photovoltaic cell structure using photo catalyst is higher than or equivalent to those of a photovoltaic cell structure using CdS. Therefore, the photovoltaic cell structure of the present invention is quite valuable in practice.

In view of the above, traditional CdS can be replaced by the n-type semiconductor layer of titanium oxide or tungsten oxide in consideration of the photo catalyst characteristic thereof, so that the contamination caused by the use of CdS can be effectively avoided.

The above-described embodiments of the present invention are intended to be illustrative only. Numerous alternative embodiments may be devised by those skilled in the art without departing from the scope of the following claims.

What is claimed is:

1. A photovoltaic cell structure, comprising:
a substrate;
a metal layer formed on a surface of the substrate;
a p-type semiconductor layer formed on the metal layer and comprising copper indium gallium selenium sulfur, copper indium gallium selenium, copper indium sulfur, copper indium selenium or comprising a compound of at least two of copper, selenium or sulfur;
an n-type semiconductor layer exhibiting photo catalyst behavior and being formed on the p-type semiconductor layer, thereby forming a p-n junction therebetween; and
a transparent conductive layer formed on the n-type semiconductor layer; and
a high resistivity layer formed between the metal layer and the transparent conductive layer.

2. The photovoltaic cell structure of claim 1, wherein the n-type semiconductor layer comprises metal oxide.

3. The photovoltaic cell structure of claim 2, wherein the metal oxide comprises titanium oxide, tungsten oxide or a semiconductor has the photo catalyst characteristic.

4. The photovoltaic cell structure of claim 1, wherein the n-type semiconductor layer has a thickness between 1 and 1000 nanometers.

5. The photovoltaic cell structure of claim 1, wherein the high resistivity layer is stacked between and is in contact with the metal layer and the p-type semiconductor layer, or between the n-type semiconductor layer and the transparent conductive layer.

6. The photovoltaic cell structure of claim 1, wherein the high resistivity layer comprises metal oxide.

7. The photovoltaic cell structure of claim 6, wherein the metal oxide is selected from the group consisting of vanadium oxide, tungsten oxide, molybdenum oxide, copper oxide, iron oxide, tin oxide, titanium oxide, zinc oxide, zirconium oxide, lanthanum oxide, niobium oxide, indium tin oxide, strontium oxide, cadmium oxide, indium oxide, or the mixture or alloys thereof.

8. The photovoltaic cell structure of claim 1, wherein the high resistivity layer comprises insulation material capable of inducing capacitive effect.

9. The photovoltaic cell structure of claim 8, wherein the insulation material is silicon or aluminum oxide.

10. The photovoltaic cell structure of claim 1, wherein the high resistivity layer comprises metal nitride.

11. The photovoltaic cell structure of claim 1, wherein the high resistivity layer has a thickness between 25 and 2000 angstroms.

12. The photovoltaic cell structure of claim 1, wherein the transparent conductive layer is selected from the group consisting of indium tin oxide, indium zinc oxide, aluminum zinc oxide, gallium zinc oxide, aluminum gallium zinc oxide, cadmium tin oxide, zinc oxide or zirconium dioxide.

13. The photovoltaic cell structure of claim 1, wherein the metal layer comprises molybdenum, chromium, vanadium or tungsten.

14. The photovoltaic cell structure of claim 1, wherein the substrate is a glass substrate, a polyimide flexible substrate, or a metal plate or a metal foil of stainless steel, molybdenum, copper, titanium or aluminum.

15. The photovoltaic cell structure of claim 1, wherein the n-type semiconductor layer exhibits increased carrier mobility when illuminated.
